(19) United States
(12) Patent Application Publication
(10) Pub. No.: US 2025/0285672 A1
(43) Pub. Date: Sep. 11, 2025

(54) DYNAMIC GAIN CELL WITH REDUCED LEAKAGE

(71) Applicant: ECOLE POLYTECHNIQUE FEDERALE DE LAUSANNE (EPFL), Lausanne (CH)

(72) Inventors: Robert GITERMAN, Lausanne (CH); Andreas BURG, Echandens-Denges (CH); Halil Andac YIGIT, Ecublens (CH)

(21) Appl. No.: 19/069,564

(22) Filed: Mar. 4, 2025

Related U.S. Application Data
(60) Provisional application No. 63/561,377, filed on Mar. 5, 2024.

(51) Int. Cl. G11C 11/405; G11C 11/4093; G11C 11/4096

(52) U.S. Cl. CPC G11C 11/405; G11C 11/4093; G11C 11/4096

(57) ABSTRACT

A 3T gain cell includes a write transistor, a storage transistor and a read transistor. The write transistor has a first diffusion connected to a write bit line (WBL), a gate connected to a write word line (WWL) and a second diffusion. The storage transistor has a gate connected to said second diffusion of said write transistor, a first diffusion connected to a read bit line (RBL), and a second diffusion. The read transistor has a gate connected to a read word line (RWL) a first diffusion connected to said second diffusion of said storage transistor, and a second diffusion connected to a reference voltage.

### CROSS REFERENCE TO RELATED APPLICATION

This application claims the benefit of priority of U.S. Provisional Patent Application No. 63/561,377, filed Mar. 5, 2024, the contents of which are all incorporated herein by reference in their entirety.

### TECHNICAL FIELD

The present disclosure, in some embodiments, thereof, relates to a gain cell and, more particularly, but not exclusively, to a three-transistor (3T) gain cell.

### BACKGROUND

Modern industry growth drivers, such as Artificial Intelligence (AI) and Machine Learning, 5G, Internet-of-Things (IOT) and automotive technologies require ever-increasing amounts of memory. However, off-chip accesses to external dynamic random access memory (DRAM) are up to one thousand times more costly in latency and power than access to on-chip memory. To limit this performance and power overhead, the amount of embedded memory on almost any integrated circuit (i.e. chip) often reaches tens to hundreds of megabits, accounting often for up-to 75% of the total chip area. Unfortunately, the cost of silicon is proportional to its area, especially in high volume manufacturing. With SRAM IP dominating the die area, any density improvement in memory may significantly reduce the overall cost of the silicon. To make things worse, SRAM scaling beyond 16 nm process technologies has been facing significant scaling difficulties, leading to only 5%-20% reduced size between technology generations, as compared to 50% reduction in logic scaling. This further aggravates the memory bottleneck and significantly limits today's application from reaching their performance and power efficiency potentials.

1T-1C embedded DRAM (eDRAM) is a traditional alternative to SRAM due to its higher density. However, it requires additional complex and costly process steps to fabricate the memory bitcell. Moreover, process scaling resulted in serious reliability issues in its fabrication, hence it is only available in very few and expensive process nodes and it is phased out beyond 14 nm.

Gain-cell RAM (GCRAM) is a fully logic-compatible alternative to SRAM and to 1T-1C eDRAM, offering a smaller bitcell size than SRAM, nondestructive read operation (as opposed to 1T-1C eDRAM), and inherent two-ported functionality. However, GCRAM is also based on dynamic storage (similar to 1T-1C eDRAM) and therefore it requires periodic refresh cycles to maintain the data, which deteriorated over time due to leakage currents from and to the storage nodes of the gain cells. This problem is particularly acute in advanced process technologies beyond 40 nm, resulting in faster deterioration of the stored data and limited data retention time, requiring frequent refresh cycles to maintain functionality and resulting in significant power overhead and reduced memory availability.

### SUMMARY OF THE INVENTION

According to some embodiments there is provided a gain cell with low gate leakage, a method for storing data in the gain cell, and a memory array of the gain cells.

Some embodiments disclosed herein present a three-transistor (3T) gain cell with low gate leakage relative to conventional 3T gain cells. The low gate leakage significantly reduces the deterioration pace of the gain cell storage node voltage, thereby significantly extending the data retention time.

3T gain cells include a write transistor, storage transistor and read transistor. The low gate leakage of embodiments presented herein is obtained by connecting the read bit line (RBL) to a diffusion of the storage transistor, as described in more detail below. This is in contrast with conventional 3T gain cells, in which the RBL is connected to a diffusion of the read transistor.

A precharge or pre-discharge element may be connected to RBL, according to the types of the read, write and storage transistors.

Effects of some of the embodiments disclosed herein may include, but are not limited to:
1) Longer data retention time, especially in scaled process technologies, down to a feature size of 5 nm and below;
2) Reduced power consumption;
3) Improved memory availability;
4) Does not incur any area or performance overheads; and
5) Does not require additional process steps or cost.

According to a first aspect of some embodiments of the disclosure there is provided a gain cell which includes a write transistor, a storage transistor and a read transistor. The write transistor has a first diffusion connected to a write bit line (WBL), a gate connected to a write word line (WWL) and a second diffusion. The storage transistor associated has a gate connected to the second diffusion of the write transistor, a first diffusion connected to a read bit line (RBL), and a second diffusion. The read transistor associated with the storage transistor, comprising a gate connected to a read word line (RWL) a first diffusion connected to the second diffusion of the storage transistor, and a second diffusion connected to a reference voltage.

According to some embodiments of the disclosure, the gain cell further includes a preset element connected to the RBL, configured for presetting a level of the first diffusion of the storage transistor. According to some further embodiments of the disclosure, the storage transistor is an n-type transistor and the presetting the level of the first diffusion of the storage transistor includes charging the first diffusion of the storage transistor to a supply voltage level (VDD). According to other further embodiments of the disclosure, the storage transistor is a p-type transistor and the presetting the level of the first diffusion of the storage transistor includes discharging the first diffusion of the storage transistor to ground.

According to some embodiments of the disclosure, the storage transistor is an n-type transistor and the reference voltage is ground.

According to some embodiments of the disclosure, the storage transistor is a p-type transistor and the reference voltage is VDD.

According to some embodiments of the disclosure, the write transistor, the storage transistor and the read transistor are field-effect transistors.

According to some embodiments of the disclosure, the write transistor, the storage transistor and the read transistor are fin field-effect transistors.

According to some embodiments of the disclosure, the write transistor, the storage transistor and the read transistor are metal-oxide-semiconductor field-effect transistors.

According to some embodiments of the disclosure, the write transistor, the storage transistor and the read transistor are fully depleted silicon on insulator transistors.

According to some embodiments of the disclosure, the write transistor, the storage transistor and the read transistor are bulk field-effect transistors.

According to a second aspect of some embodiments of the disclosure there is provided a method of storing data in a gain cell. The gain cell includes:
a write transistor, comprising a first diffusion connected to a write bit line (WBL), a gate connected to a write word line (WWL) and a second diffusion;
a storage transistor associated with the write transistor, comprising a gate connected to the second diffusion of the write transistor, a first diffusion connected to a read bit line (RBL), and a second diffusion; and
a read transistor associated with the storage transistor, comprising a gate connected to a read word line (RWL) a first diffusion connected to the second diffusion of the storage transistor, and a second diffusion connected to a reference voltage,
   The method includes:
writing to the gain cell by applying a data signal to the WBL and connecting the WBL to the gate of the storage transistor by providing a write trigger signal to the WWL;
presetting the first diffusion of the storage transistor to a preset level; and
reading from the gain cell by connecting the storage node to the RBL by providing a read trigger signal to RWL.

According to some embodiments of the disclosure, the storage transistor is an n-type transistor and the presetting the level of the first diffusion of the storage transistors includes charging the first diffusion of the storage transistor to a supply voltage level (VDD). According to some alternate embodiments of the disclosure, the storage transistor is a p-type transistor and the presetting the level of the first diffusion of the storage transistors comprises discharging the first diffusion of the storage transistor to ground.

According to some embodiments of the disclosure, the storage transistor is an n-type transistor and the reference voltage is ground.

According to some embodiments of the disclosure, the storage transistor is a p-type transistor and the reference voltage is VDD.

According to some embodiments of the disclosure, write transistor, the storage transistor and the read transistors are field-effect transistors.

According to some embodiments of the disclosure, the method further includes presetting the first diffusion of the storage transistor after the reading from the gain cell.

According to some embodiments of the disclosure, the method further includes presetting the first diffusion of the storage transistor during non-read operation.

According to third aspect of some embodiments of the disclosure there is provided a memory. The memory includes a data write interface for inputting data written to the memory, a data read interface for outputting data read from the memory and an array of gain cells associated with the data write interface and the data read interface. The array of gain cells stores data input at the data write interface and outputs stored data to the data read interface. At least some of the gain cells respectively include:
a write transistor, comprising a first diffusion connected to a write bit line (WBL), a gate connected to a write word line (WWL) and a second diffusion;
a storage transistor associated with the write transistor, comprising a gate connected to the second diffusion of the write transistor, a first diffusion connected to a read bit line (RBL), and a second diffusion; and
a read transistor associated with the storage transistor, comprising a gate connected to a read word line (RWL) a first diffusion connected to the second diffusion of the storage transistor, and a second diffusion connected to a reference voltage.

According to some embodiments of the disclosure, the memory further includes preset unit connected to the RBLs of the gain cells, configured for presetting respective levels of the first diffusion of the storage transistors.

According to some embodiments of the disclosure, the storage transistors comprise n-type transistors and the reference voltage is ground.

According to some embodiments of the disclosure, the storage transistor comprises a p-type transistor and the reference voltage is VDD.

According to some embodiments of the disclosure, the write transistor, the storage transistor and the read transistors are field-effect transistors.

Unless otherwise defined, all technical and/or scientific terms used within this document have meaning as commonly understood by one of ordinary skill in the art/s to which the present disclosure pertains. Methods and/or materials similar or equivalent to those described herein can be used in the practice and/or testing of embodiments of the present disclosure, and exemplary methods and/or materials are described below.

Regarding exemplary embodiments described below, the materials, methods, and examples are illustrative and are not intended to be necessarily limiting.

Some embodiments of the present disclosure are embodied as a semiconductor device, system or method, or computer program product. For example, some embodiments of the present disclosure may take the form of an entirely hardware embodiment or an embodiment combining software and hardware aspects that may all generally be referred to herein as a “circuit,” “module” and/or “system.”

Implementation of the method and/or system of some embodiments of the present disclosure can involve performing and/or completing selected tasks manually, automatically, or a combination thereof. According to actual instrumentation and/or equipment of some embodiments of the method and/or system of the present disclosure, several selected tasks could be implemented by hardware, by software or by firmware and/or by a combination thereof, e.g., using an operating system.

For example, hardware for performing selected tasks according to some embodiments of the present disclosure could be implemented as a chip, as part of a chip or a circuit. As software, selected tasks according to some embodiments of the present disclosure could be implemented as a plurality of software instructions being executed by a computational device e.g., using any suitable operating system.

In some embodiments, one or more tasks according to some exemplary embodiments of method and/or system as described herein are performed by a data processor, such as a computing platform for executing a plurality of instructions. Optionally, the data processor includes a volatile memory for storing instructions and/or data and/or a non-volatile storage e.g., for storing instructions and/or data. Optionally, a network connection is provided as well. User interface/s e.g., display/s and/or user input device/s are optionally provided.

Some embodiments of the present disclosure may be described below with reference to flowchart illustrations and/or block diagrams. For example illustrating exemplary methods and/or apparatus (systems) according to embodiments of the present disclosure.

The flowchart and block diagrams in the Figures illustrate the architecture, functionality, and operation of possible implementations of chips, systems and methods, according to various embodiments of the disclosed subject matter. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions. Further, block diagrams may represent hardware components that coexist and operate in parallel, exchanging information and/or interacting through connections between them.

### BRIEF DESCRIPTION OF THE DRAWINGS

In order to understand the invention, embodiments will now be described, by way of non-limiting example only, with reference to the accompanying drawings. Features shown in the drawings are meant to be illustrative of only some embodiments of the presently disclosed subject matter, unless otherwise indicated. In the drawings like reference numerals are used to indicate corresponding parts.

In block diagrams and flowcharts, optional elements/components and optional stages may be included within dashed boxes.

In the figures:

FIG. 1 is a simplified block diagram of a gain cell, according to some embodiments of the presently disclosed subject matter;

FIGS. 2A-2B are simplified block diagrams of preset elements, according to respective exemplary embodiments of the presently disclosed subject matter;

FIGS. 3-4 are simplified circuit diagrams of 3T gain cells, according to respective exemplary embodiments of the presently disclosed subject matter;

FIG. 5 is a simplified flowchart of a method of storing data in a gain cell, according to some embodiments of the presently disclosed subject matter;

FIG. 6 is a simplified block diagram of a memory array, according to some embodiments of the presently disclosed subject matter; and

FIG. 7 presents simulation results for storage node voltages of a gain cell in accordance with some embodiments of the presently disclosed subject matter.

The various embodiments of the presently disclosed subject matter are described below with reference to the drawings, which are to be considered in all aspects as illustrative only and not restrictive in any manner.

Elements illustrated in the drawings are not necessarily to scale. Moreover, two different objects in the same figure may be drawn to different scales.

### DETAILED DESCRIPTION OF EMBODIMENTS

The present disclosure, in some embodiments, thereof, relates to a gain cell and, more particularly, but not exclusively, to a three-transistor gain cell.

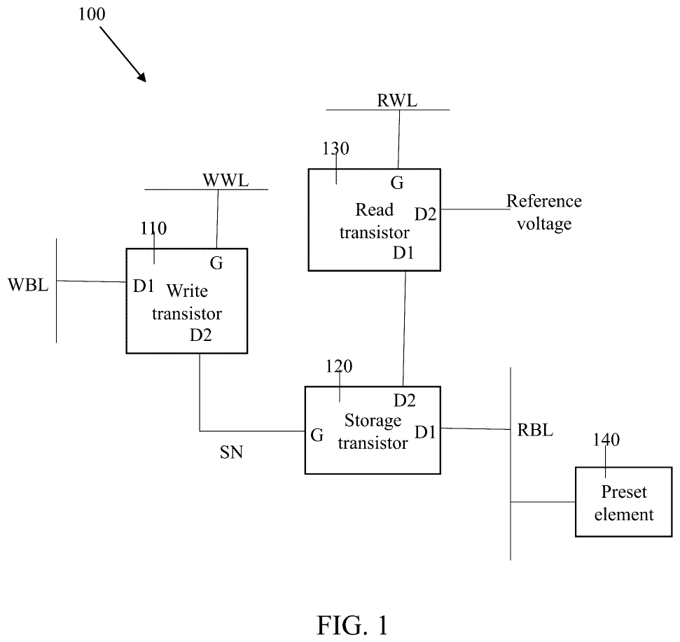

A 3-transistor (3T) gain cell according to embodiments of the presently disclosed subject matter includes a write transistor, a storage transistor and a read transistor (for example see FIG. 1). The data is stored on a storage node formed at the junction of a diffusion of the write transistor and the gate of the storage transistor.

The performance and data retention time of the 3T gain cell is dictated by how rapidly the RBL discharges or charges, depending on whether an NMOS transistor or a PMOS transistor is used for the read operation (where the gain cell stores a logic ‘1’ or a logic ‘0’ respectively). The difference in discharge/charge rate during a read operation depends on the level of the SN. The level of the SN is initially set during a write operation depending on the data and degrades over time due to leakage. If for an NMOS read transistor the SN level for a ‘1’ is too low (e.g. below a given threshold) or for a PMOS read transistor the SN level for a ‘0’ is too high (e.g. above a given threshold), a reliable read is no longer possible. As the levels approach the threshold, a read operation may also require a longer time which degrades the speed of the memory.

During retention mode, the write transistor is off and the SN voltage deteriorates due to leakage. How fast the SN voltage deteriorates depends on the leakage current magnitude and the total storage node capacitance which includes the parasitic FET capacitances of the transistors connected to the SN.

In conventional NMOS read 3T GCRAM cells, the storage transistor diffusion that is not connected to the read transistor is connected to GND resulting in significant gate tunneling leakage from SN through the storage transistor. This reduces the speed and reliability at which a logic ‘0’ may be read from the gain cell and reduces the data retention time of ‘1’, which impose a severe penalty on reliability and performance. A corresponding effect occurs in the PMOS read implementation, where leakage from VDD (which is connected to the diffusion of the storage transistor that is not connected to the read transistor) due to gate tunnelling to the storage node reduces the speed and reliability at which a logic ‘0’ may be read from the gain cell limiting data retention time.

Embodiments of the presently disclosed subject matter in which the storage transistor is an NMOS transistor (i.e. NMOS read implementation) improve the data retention time of data ‘1’ storage by connecting the RBL to one of the diffusions of the storage transistor and the reference level to one of the diffusions of the read transistor. The RBL is pre-charged to set the voltage of the RBL signal to VDD during non-read operations. During a read operation, the RBL is conditionally discharged when the storage node level is high and otherwise remains closer to its initial state. The outcome is a very strong retention of data ‘1’ due to the positive leakage direction which strengthens the ‘1’ SN voltage level. Furthermore, the data retention time of data ‘0’ is not significantly degraded due to the lower gate leakage in this direction. This improvement is obtained while maintaining the same gain cell dimensions and similar gain cell functionality without any other modifications needed at the memory periphery.

Embodiments of the presently disclosed subject matter in which the storage transistor is a PMOS transistor (i.e. PMOS read implementation) improve the data retention time of data ‘0’ storage by connecting the RBL to one of the diffusions of the storage transistor and the reference level to one of the diffusions of the read transistor. The RBL is pre-discharged to set the voltage of the RBL signal to GND during non-read operations. During a read operation, the RBL is conditionally charged when the storage node level is low and otherwise remains closer to its initial state. The outcome is a very strong retention of data ‘0’ due to the negative leakage direction which strengthens the ‘0’ SN voltage level. Furthermore, the data retention time of data ‘1’ is not significantly degraded due to the lower gate leakage for this direction. This improvement is obtained while maintaining the same gain cell dimensions and similar gain cell functionality without any other modifications needed at the memory periphery.

The principles, uses and implementations of the teachings herein may be better understood with reference to the accompanying description and figures. Upon perusal of the description and figures present herein, one skilled in the art will be able to implement the teachings herein without undue effort or experimentation.

Before explaining at least one embodiment in detail, it is to be understood that embodiments are not necessarily limited in its application to the details of construction and the arrangement of the components and/or methods set forth in the following description and/or illustrated in the drawings and/or the Examples.

### Gain Cell

Referring now to the drawings, FIG. 1 is a simplified block diagram of a gain cell, according to some embodiments of the presently disclosed subject matter.

Gain cell 100 includes three transistors, write transistor 110, storage transistor 120 and read transistor 130.

Write transistor 110 has diffusion D1 connected to the write bit line (WBL), gate G connected to the write word line (WWL) and diffusion D2 connected to the gate of storage transistor 120. This connection forms storage node SN.

Storage transistor 120 has a diffusion D1 connected to the read bit line (RBL), and a diffusion D2 connected to diffusion D1 of read transistor 130.

Read transistor 130 has gate G connected to the read word line (RWL) and a diffusion D2 connected to a reference voltage. The level of the reference voltage is based on the type of storage transistor 120, as described in more detail herein.

According to some embodiments, storage transistor 120 is an n-type transistor, the reference level is GND and the RBL is held at the supply voltage (VDD) during non-read operation. According to some alternate embodiments, storage transistor 120 is a p-type transistor, the reference level is the supply voltage level (VDD) and the RBL is held at GND during non-read operation.

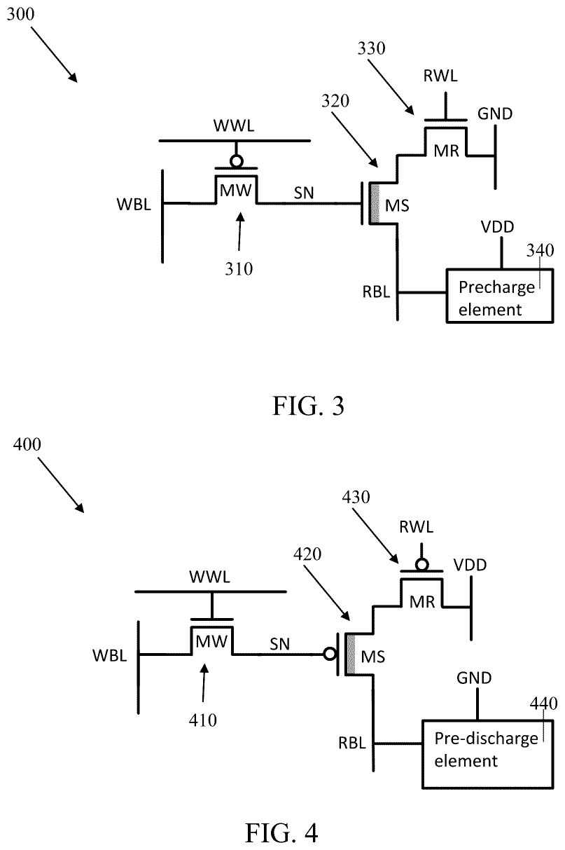

According to some embodiments of the presently disclosed subject matter, write transistor 110 is a p-type transistor (e.g. as shown in FIG. 3). According to alternate embodiments of the presently disclosed subject matter, write transistor 110 is an n-type transistor (e.g. as shown in FIG. 4).

According to some embodiments of the presently disclosed subject matter, read transistor 130 is an n-type transistor (e.g. as shown in FIG. 3). According to alternate embodiments of the presently disclosed subject matter, write transistor 110 is a p-type transistor (e.g. as shown in FIG. 4).

Optionally, write transistor 110, read transistor 120 and storage transistor 130 are field-effect transistors (FETs).

As used herein, according to some embodiments of the presently disclosed subject matter, the terms “field-effect transistor” and “FET” include any type of known or future FETs and/or FET process technologies.

Examples of types of FETs include: metal-oxide-semiconductor FET (MOSFET), fin FET (FinFET), Fully Depleted Silicon On Insulator (FDSOI) FET, Bulk Complementary metal-oxide-semiconductor (CMOS), or Gate All Around (GAA) FET.

In a first optional embodiment, write transistor 110, read transistor 120 and storage transistor 130 are fin field-effect transistors (finFET).

In a second optional embodiment, write transistor 110, read transistor 120 and storage transistor 130 are metal-oxide-semiconductor field-effect transistors (MOSFETs).

In a third optional embodiment, write transistor 110, read transistor 120 and storage transistor 130 are fully depleted silicon on insulator (FD-SOI) transistors.

In a fourth optional embodiment, write transistor 110, read transistor 120 and storage transistor 130 are bulk FETs.

Optionally, gain cell 100 further includes preset element 140 which is connected to the RBL. Preset element 140 sets the level of storage transistor diffusion D1 (and consequently RBL) just before a read operation (before activating the RWL), and optionally during a non-read operation of the gain cell (e.g. when gain cell 100 is in “standby” between reads). The read operation alters the RBL voltage level according to the data.

Because RBL connects to storage transistor 130 the level at RBL has an effect on SN leakage and may be selected to maximize SN integrity. This is not the case in conventional 3T gain cells in which the level at RBL has no significant effect on SN leakage.

The preset level may be based on type of storage transistor. According to some embodiments, storage transistor 120 is an n-type transistor and preset element 140 charges RBL to VDD during preset. According to some alternate embodiments, storage transistor 120 is a p-type transistor and preset element 140 charges discharges RBL to ground during preset. Exemplary embodiments are described herein with reference to FIGS. 3-4.

As used herein, according to some embodiments of the presently disclosed subject matter, the term “reference voltage” encompasses supply voltage VDD, ground and/or any other voltage or level used as a reference for gain cell operation.

As used herein, according to some embodiments of the presently disclosed subject matter, the term “non-read operation” means the times during which data is being written to the gain cell and the time period during which the data is being kept (i.e. being stored) in the gain cell.

As used herein, according to some embodiments of the presently disclosed subject matter, the term “preset level” encompasses supply voltage VDD, ground (GND) and/or any other voltage or level used as a preset voltage for the RBL for gain cell operation.

As used herein, according to some embodiments of the presently disclosed subject matter, the term “preset” means the operation(s) which establish a preset level at RBL (and the corresponding connected diffusion or diffusions).

Further optionally, preset element 140 also presets the level of storage transistor D1 before performing a read operation. The level set for a read operation may be the same as the preset level during non-read operations or may differ from it.

Optionally, the timing at which preset element 140 establishes the levels at the RBL is controlled by external signals applied to preset element 140. Alternately or additionally, preset element 140 includes internal logic which controls and/or adjusts the timing of the operations required to set RBL to the reference level.

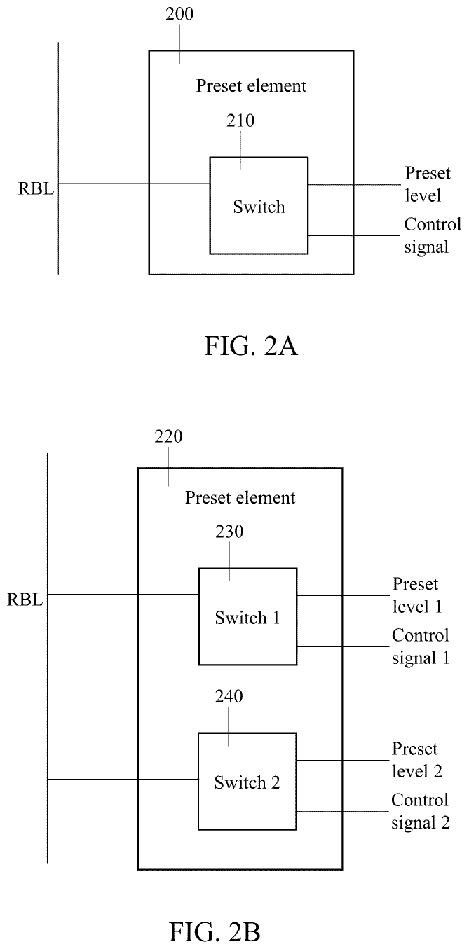

Reference is now made to FIGS. 2A-2B which are simplified block diagrams of preset elements, according to respective exemplary embodiments of the presently disclosed subject matter.

Preset element 200 includes switch 210 which is controlled by a control signal which opens or closes switch 210. During preset, RBL is connected to the preset level via switch 210. At other times RBL may be disconnected. In the present exemplary embodiment, the same preset level is used for a read operation and during non-read operation.

In one example switch 210 is a transistor with the control signal connected to the gate, and with RBL and the reference level connected to respective diffusions.

Preset element 220 has a similar configuration, with switches 230 and 240 connected to RBL. Based on the levels of control signal 1 and control signal 2, RBL may be connected to preset voltage 1 or to preset voltage 2. This enables presetting RBL to different levels during non-read operations and before read operations.

Optionally, the preset level(s) are selected to maximize protection of the SN.

Reference is now made to FIG. 3, which is a simplified circuit diagram of a 3T gain cell, according to some exemplary embodiments of the presently disclosed subject matter. Gain cell 300 is an NMOS read implementation, and includes NMOS storage transistor MS 320, PMOS write transistor MW 310 and NMOS read transistor MR 330.

The gate of MW 310 is connected to the WWL and one diffusion is connected to WBL. The second diffusion of MW 310 is connected to the gate of MS 320, forming a storage node SN. One diffusion of MS 320 is connected to a diffusion of MR 330 and the second diffusion of MS 320 is connected to RBL. The gate of MR 330 is connected to the RWL. One diffusion of MR 330 is connected to a diffusion of MS 320 and the second diffusion is connected to GND.

During non-read operation, RBL is preset to VDD. Thus when a logic ‘1’ level is stored at the storage node, there is positive leakage from RBL to SN (effectively charging the ‘1’ logic level). When a logic ‘0’ level is stored at the storage node, the leakage from RBL to SN through MS 320 is very low in this direction.

Optionally, RBL is also connected to precharge element 340 which charges the RBL, at least during non-read operations as described above.

Reference is now made to FIG. 4, which is a simplified circuit diagram of a 3T gain cell, according to some exemplary embodiments of the presently disclosed subject matter. Gain cell 400 is a PMOS read implementation. Gain cell 400 includes PMOS storage transistor MS 420, NMOS write transistor MW 410 and PMOS read transistor MR 430.

The gate of MW 410 is connected to the WWL and one diffusion is connected to WBL. The second diffusion of MW 410 is connected to the gate of MS 420, forming a storage node SN. One diffusion of MS 420 is connected to a diffusion of MR 430 and the second diffusion of MS 420 is connected to RBL. The gate of MR 430 is connected to the RWL. One diffusion of MR 430 is connected to a diffusion of MS 420 and the second diffusion is connected to GND.

Optionally, RBL is also connected to pre-discharge element 440 which discharges the RBL, at least during non-read operations as described above.

### Method of Storing Data in a Gain Cell

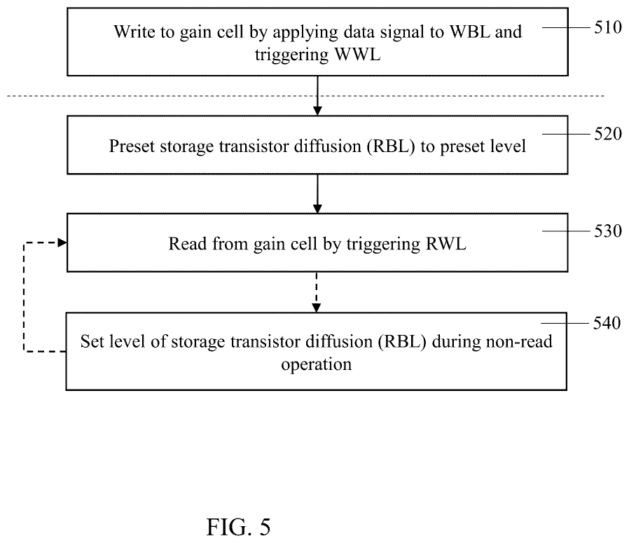

Reference is now made to FIG. 5, which is a simplified flowchart of a method of storing data in a gain cell, according to some embodiments of the presently disclosed subject matter. Embodiments of this method preserve the stored data in the same (and optionally in other gain cells connected to same RBL) very reliably.

The gain cell includes a write transistor, storage transistor and read transistor. The write transistor includes a first diffusion connected to a write bit line (WBL), a gate connected to a write word line (WWL) and a second diffusion. The storage transistor includes a gate connected to the second diffusion of the write transistor, a first diffusion connected to a read bit line (RBL), and a second diffusion. The read transistor includes a gate connected to a read word line (RWL) a first diffusion connected to the second diffusion of the storage transistor, and a second diffusion connected to a reference voltage.

The types of the write transistor, storage transistor and read transistor may be in accordance with any embodiment of the 3T transistor described herein.

Optionally, multiple gain cells having the same configuration are connected to the same RBL (e.g. in a memory array).

In 510 a logic level is written to the gain cell by applying a data signal to the WBL and providing a write trigger signal to the WWL, thereby connecting the WBL to the gate of the storage transistor.

In 520 the first diffusion of the storage transistor is preset to the preset level for the read operation.

Optionally, the first diffusion of the storage transistor is preset to the preset level by a preset element connected to the RBL.

Optionally, the preset operation is skipped before a read operation if the RBL is already at an acceptable preset level for the read operation.

Optionally, the storage transistor is an n-type transistor and the preset level is VDD.

Optionally, the storage transistor is a p-type transistor and the preset level is GND.

In 530 the logic level is read from the gain cell by providing a read trigger signal to RWL, thereby connecting the reference voltage to the second diffusion of the storage transistor.

Optionally, the first diffusion of the storage transistor is preset again to the preset level for the read operation if another read operation follows.

Optionally, at 540 the method further includes setting the level of the RBL to a preset level during non-read operation of the gain cell.

Pre-setting the level of the RBL during non-read operation may be performed once or multiple times.

Optionally, 540 is repeated regularly, for example after a write operation and/or without a prior read operation and/or without a prior read preset operation.

Optionally, RBL is set to the same level during both before a read operation and during non-read operation. Alternately, RBL is set to different levels before a read operation and during non-read operation.

The preset level(s) may be selected to maximize the integrity of the SN, so that the level at RBL best protects the level at SN before a read operation and during non-read operation.

Optionally, the write transistor, the storage transistor and the read transistors are field-effect transistors. Further optionally the type of the write transistor, the storage transistor and the read transistors is one of: metal-oxide-semiconductor FET (MOSFET), fin FET (FinFET), Fully Depleted Silicon On Insulator (FDSOI) FET, Bulk Complementary metal-oxide-semiconductor (CMOS), and Gate All Around (GAA) FET.

### Memory Array

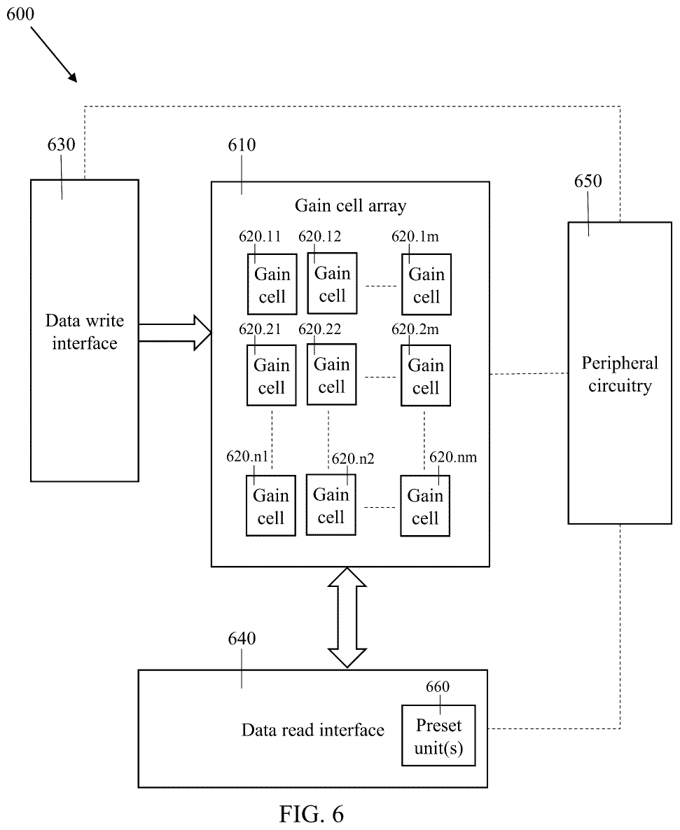

Reference is now made to FIG. 6, which is a simplified block diagram of a memory array, according to some embodiments of the presently disclosed subject matter. For clarity, the inner connections to each gain cell in the array (e.g. RWL, RBL, WWL, RWL, VDD, GND, etc.) are not explicitly shown, but their layout and connections will be apparent to the skilled individual.

Memory array 600 includes gain cell array 610, data write interface 630 and data read interface 640.

Gain cell array 610 includes gain cells 620.11-620.nm. At least some of the gain cells include a respective write transistor, storage transistor and read transistor, connected according to any embodiment of the gain cell of the presently disclosed subject matter.

Data write interface 630 inputs data to be written to the memory.

Data read interface 640 outputs data read from the memory.

Although illustrated in FIG. 6 as separate components, data write interface and data read interface may be implemented as separate circuitry, the same circuitry or may share circuitry.

Optionally, the storage transistor is an n-type transistor and the preset level is VDD.

Optionally, the storage transistors are n-type transistors and the reference voltage is ground.

Optionally, the storage transistors are p-type transistors and the preset level is GND.

Optionally, the storage transistors are p-type transistors and the reference voltage is VDD.

Optionally, the write transistors, the storage transistors and the read transistors are FETs.

Types of FETs which may be suitable for the write transistors, the storage transistors and the read transistors include but are not limited to: metal-oxide-semiconductor FET (MOSFET), fin FET (FinFET), Fully Depleted Silicon On Insulator (FDSOI) FET, Bulk Complementary metal-oxide-semiconductor (CMOS), and Gate All Around (GAA) FET.

Optionally, memory array 600 includes peripheral circuitry 650, as needed for functioning of memory array 600. Examples of peripheral circuitry for memory arrays includes but is not limited to: decoders, sense amplifiers, drivers, buffers, error correction circuitry, timing control circuitry, etc.

Optionally, memory array 600 includes preset unit 660 which is connected to the gain cell RBLs. Preset unit 660 presets respective levels of the storage transistor diffusions during read and non-read operations of the gain cell, as described herein.

Optionally, preset unit(s) 660 is part of data read interface 640. For clarity preset unit(s) 660 is illustrated as a single unit that connects to all RBLs. However multiple preset units may be used, each connecting to one or more RBLs.

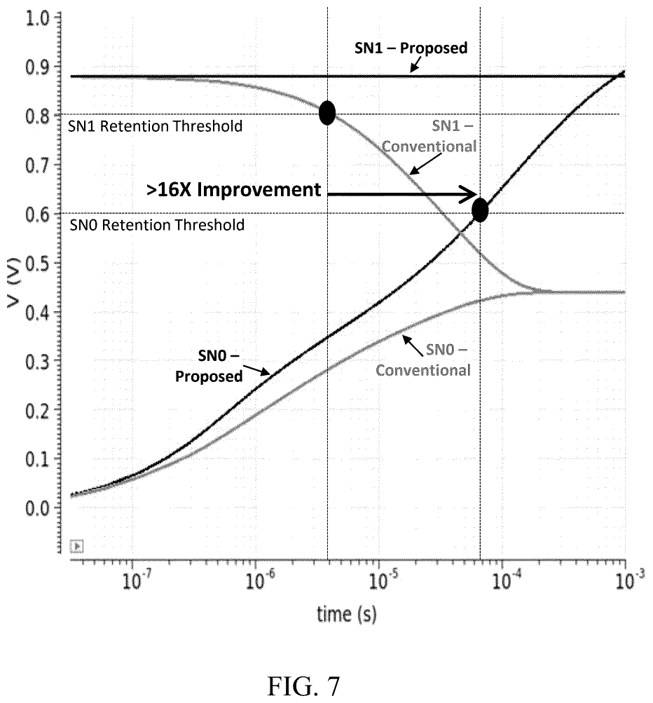

Reference is now made to FIG. 7, which presents simulation results demonstrating the advantages of a gain cell in accordance with some embodiments of the invention that are based on an NMOS storage transistor. FIG. 7 illustrates the storage node voltages simulated under a Fast-Fast corner at 125 C at a 16 nm FinFET process. The blue curves present the deterioration of the SN voltages according to embodiments of the invention, with RBL connected to a diffusion of the storage transistor and a preset voltage for RBL during non-read of VDD. The red curves denoted by “SN0—conventional” and “SN1—conventional” present the deterioration of the storage node voltages (SN1 for ‘1’ and SN0 for ‘0’) of the conventional 3T configuration, with RBL connected to a diffusion of the read transistor and the diffusion of the storage transistor connected to a reference voltage of GND. The horizontal dashed lines specify the thresholds for ‘1’ (top) and ‘0’ (bottom) which define the allowed ranges for each storage level for correct and reliable read according to the performance specifications. The threshold for SN1 is dictated by the target read performance in order to enable sufficient drive strength of the read port to discharge the RBL, while the threshold for SN0 is specified to prevent a fast discharge of the RBL during read ‘0’ operation, which would result in a read failure. The gain cell data retention time is defined as the earliest crossing of either of the SN0 or SN1 thresholds. The resulting data retention time of the 3T configuration according to the simulated embodiment presents over sixteen times data retention time improvement over the conventional 3T gain cell (with RBL connected to a read transistor diffusion). This results in over a sixteen times reduction in the memory refresh power consumption, and significant improvement in memory availability due to the reduction in overall refresh cycles occupying the memory.

### GENERAL

The terms “comprises”, “comprising”, “includes”, “including”, “having” and their conjugates mean “including but not limited to”.

The term “consisting of” means “including and limited to”.

As used herein, singular forms, for example, “a”, “an” and “the” include plural references unless the context clearly dictates otherwise.

Within this application, various quantifications and/or expressions may include use of ranges. Range format should not be construed as an inflexible limitation on the scope of the present disclosure. Accordingly, descriptions including ranges should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within the stated range and/or subrange, for example, 1, 2, 3, 4, 5, and 6. Whenever a numerical range is indicated within this document, it is meant to include any cited numeral (fractional or integral) within the indicated range.

It is appreciated that certain features which are (e.g., for clarity) described in the context of separate embodiments, may also be provided in combination in a single embodiment. Where various features of the present disclosure, which are (e.g., for brevity) described in a context of a single embodiment, may also be provided separately or in any suitable sub-combination or may be suitable for use with any other described embodiment. Features described in the context of various embodiments are not to be considered essential features of those embodiments, unless the embodiment is inoperative without those elements.

Although the present disclosure has been described in conjunction with specific embodiments thereof, it is evident that many alternatives, modifications, and variations will be apparent to those skilled in the art. Accordingly, this application intends to embrace all such alternatives, modifications and variations that fall within the spirit and broad scope of the appended claims.

All references (e.g., publications, patents, patent applications) mentioned in this specification are herein incorporated in their entirety by reference into the specification, e.g., as if each individual publication, patent, or patent application was individually indicated to be incorporated herein by reference. Citation or identification of any reference in this application should not be construed as an admission that such reference is available as prior art to the present disclosure. In addition, any priority document(s) and/or document(s) related to this application (e.g., co-filed) are hereby incorporated herein by reference in its/their entirety.

Where section headings are used in this document, they should not be interpreted as necessarily limiting.

1. A gain cell, comprising:
a write transistor, comprising a first diffusion connected to a write bit line (WBL), a gate connected to a write word line (WWL) and a second diffusion;
a storage transistor associated with said write transistor, comprising a gate connected to said second diffusion of said write transistor, a first diffusion connected to a read bit line (RBL), and a second diffusion; and
a read transistor associated with said storage transistor, comprising a gate connected to a read word line (RWL) a first diffusion connected to said second diffusion of said storage transistor, and a second diffusion connected to a reference voltage.

2. The gain cell of claim 1, further comprising a preset element connected to said RBL, configured for presetting a level of said first diffusion of said storage transistor.

3. The gain cell of claim 2, wherein said storage transistor comprises an n-type transistor and said presetting said level of said first diffusion of said storage transistor comprises charging said first diffusion of said storage transistor to a supply voltage level (VDD).

4. The gain cell of claim 2, wherein said storage transistor comprises a p-type transistor and said presetting said level of said first diffusion of said storage transistor comprises discharging said first diffusion of said storage transistor to ground.

5. The gain cell of claim 1, wherein said storage transistor comprises an n-type transistor and said reference voltage is ground.

6. The gain cell of claim 1, wherein said storage transistor comprises a p-type transistor and said reference voltage is VDD.

7. The gain cell of claim 1, wherein said write transistor, said storage transistor and said read transistor are field-effect transistors.

8. The gain cell of claim 1, wherein said write transistor, said storage transistor and said read transistor are fin field-effect transistors.

9. The gain cell of claim 1, wherein said write transistor, said storage transistor and said read transistor are metal-oxide-semiconductor field-effect transistors.

10. The gain cell of claim 1, wherein said write transistor, said storage transistor and said read transistor are fully depleted silicon on insulator transistors.

11. The gain cell of claim 1, wherein said write transistor, said storage transistor and said read transistor are bulk field-effect transistors.

12. A method of storing data in a gain cell, said method comprising:
for a gain cell comprising:
a write transistor, comprising a first diffusion connected to a write bit line (WBL), a gate connected to a write word line (WWL) and a second diffusion;
a storage transistor associated with said write transistor, comprising a gate connected to said second diffusion of said write transistor, a first diffusion connected to a read bit line (RBL), and a second diffusion; and
a read transistor associated with said storage transistor, comprising a gate connected to a read word line (RWL) a first diffusion connected to said second diffusion of said storage transistor, and a second diffusion connected to a reference voltage,
writing to said gain cell by applying a data signal to said WBL and connecting said WBL to said gate of said storage transistor by providing a write trigger signal to said WWL;
presetting said first diffusion of said storage transistor to a preset level; and
reading from said gain cell by connecting said storage node to said RBL by providing a read trigger signal to RWL.

13. The method of claim 12, wherein said storage transistor comprises an n-type transistor and said presetting said level of said first diffusion of said storage transistors comprises charging said first diffusion of said storage transistor to a supply voltage level (VDD).

14. The method of claim 12, wherein said storage transistor comprises a p-type transistor and said presetting said level of said first diffusion of said storage transistors comprises discharging said first diffusion of said storage transistor to ground.

15. The method of claim 12, wherein said storage transistor comprises an n-type transistor and said reference voltage is ground.

16. The method of claim 12, wherein said storage transistor comprises a p-type transistor and said reference voltage is VDD.

17. The method of claim 12, wherein said write transistor, said storage transistor and said read transistors are field-effect transistors.

18. The method of claim 12, further comprising presetting said first diffusion of said storage transistor after said reading from said gain cell.

19. A memory comprising:
a data write interface configured to input data written to said memory;
a data read interface configured to output data read from said memory; and
an array of gain cells associated with said data write interface and said data read interface, configured to store data input at said data write interface and to output stored data to said data read interface, at least some of said gain cells respectively comprising:
a write transistor, comprising a first diffusion connected to a write bit line (WBL), a gate connected to a write word line (WWL) and a second diffusion;
a storage transistor associated with said write transistor, comprising a gate connected to said second diffusion of said write transistor, a first diffusion connected to a read bit line (RBL), and a second diffusion; and
a read transistor associated with said storage transistor, comprising a gate connected to a read word line (RWL) a first diffusion connected to said second diffusion of said storage transistor, and a second diffusion connected to a reference voltage.

20. The memory of claim 19, further comprising a preset unit connected to said RBLs of said gain cells, configured for presetting respective levels of said first diffusion of said storage transistors.

21. The memory of claim 19, wherein said storage transistors comprise n-type transistors and said reference voltage is ground.

22. The memory of claim 19, wherein said storage transistor comprises a p-type transistor and said reference voltage is VDD.

23. The memory of claim 19, wherein said write transistor, said storage transistor and said read transistors are field-effect transistors.
